(19) United States
(12) Patent Application Publication
(10) Pub. No.: US 2023/0327347 A1
(43) Pub. Date: Oct. 12, 2023

(54) ELECTRICAL SAFETY SYSTEM

(71) Applicant: CONDUCTOR HUB PTY LTD, Oxenford (AU)

(72) Inventor: Austen RITCHIE, Oxenford (AU)

(21) Appl. No.: 18/022,269

(22) PCT Filed: Aug. 22, 2021
(86) PCT No.: PCT/AU2021/050931

§ 371 Date: Feb. 20, 2023

(30) Foreign Application Priority Data
Aug. 26, 2020 (AU) 2020903046

(51) Int. Cl. H01R 4/64; H01R 4/56; H01R 4/30; E04C 5/16; E04G 15/06; G01R 31/52

(52) U.S. Cl. CPC H01R 4/64; H01R 4/56; H01R 4/307; E04C 5/16; E04G 15/061; G01R 31/52

(57) ABSTRACT

An electrical safety system is provided that includes a conductive coupler, for coupling the electrical safety system to a conductive element and be cast into concrete or similar material with the conductive element; and a housing, coupled to the conductive coupler, configured to be at least partially cast into the concrete or similar material to provide external access to the conductive coupler and thereby the conductive element. A length of the housing is adjustable after being cast into the concrete or similar material to enable the housing to sit flush with a finished surface of or associated with the concrete.

### TECHNICAL FIELD

The present invention relates to improved electrical safety, and in particular, although not exclusively, to earth testing of conductive elements, such as reinforcing bar, in concrete.

### BACKGROUND ART

Metal reinforcing (rebar) is typically used to reinforce concrete structures. As such metal reinforcing is conductive, it is typically earthed (grounded) to a common electrical earth. In case of an electrical fault, where the reinforcing becomes “live”, it is immediately directed to the earth, upon which a circuit breaker may detect the fault and interrupt the circuit.

As the conductive reinforcing is connected to a common earth, along with other conductive elements, the reinforcing has substantially the same electrical potential as the conductive elements, and as such, electric current is unlikely to flow between objects (e.g. by a person), even in case of a fault.

A problem, however, with such conductive reinforcing of the prior art is that it is difficult to later test that the reinforcing is properly connected to earth. As an illustrative example, once a concrete structure is poured and cured, the reinforcing bars of the concrete are no longer accessible to test.

In certain jurisdictions, a thick copper wire is used to electrically connect reinforcing, to reduce the likelihood that parts of reinforcing become disconnected from the earth, or disconnected from each other. However, such copper wire is also cast into the concrete, and cannot be tested once the concrete structure is poured and cured.

Australian/New Zealand Standard 3000:2018 requires that an equipotential bonding conductor be connected between the conductive reinforcing and the earthing conductors associated with the area. However, conformance with the Standard can typically only be verified by exposing the reinforcing bars, and thus destructively. Such process is obviously costly, time consuming and inconvenient, as it damages the structure.

Finally, certain systems exist that enable earth points to be provided in concrete. These systems are not, however, well suited to areas which are tiled, paved, or where a well-defined finished concrete surface is not provided. In many cases, these systems are also relatively expensive, which is compounded when many earth test points need to be provided.

As such, there is clearly a need for an improved electrical safety system.

It will be clearly understood that, if a prior art publication is referred to herein, this reference does not constitute an admission that the publication forms part of the common general knowledge in the art in Australia or in any other country.

### SUMMARY OF INVENTION

The present invention is directed to electrical safety systems which may at least partially overcome at least one of the abovementioned disadvantages or provide the consumer with a useful or commercial choice.

With the foregoing in view, the present invention in one form, resides broadly in an electrical safety system comprising:

a conductive coupler, for coupling the electrical safety system to a conductive element and be cast into concrete or similar material with the conductive element; and

a housing, coupled to the conductive coupler, configured to be at least partially cast into the concrete or similar material to provide external access to the conductive coupler and thereby the conductive element,

wherein a length of the housing is adjustable after being cast into the concrete or similar material to enable the housing to sit flush with a finished surface of or associated with the concrete.

Advantageously, the electrical safety system allows for earthing of conductive elements in concrete, such as reinforcing and copper wire, to be easily tested. As the length of the housing is adjustable, the system is particularly useful when distance between the conductive coupler and a finished outer surface of the concrete is not known. This is, for example, the case when the type of finished outer surface (e.g. tiles or pavers) it is not known at the time the concrete (or similar material) is cast.

The system enables faults in earthing to be more easily identifiable, which in turn increases electrical safety. Furthermore, inspection costs are reduced, and invasive inspection techniques are not necessary.

Preferably, the housing is configured to be cut to length after being cast into the concrete.

Preferably, the housing is sealable. Suitably, the housing is adapted to be sealed by a conductive member that extends from an outside of the housing, through the housing, to the conductive coupler. The conductive member may include a threaded portion, configured to engage with a corresponding threaded portion of the conductive coupler.

The conductive member may comprise a threaded bolt. The threaded bolt may include a domed cap.

The conductive member may be adjustable in length. The conductive member may include a plurality of threaded portions, separated by narrow portions, thereby defining adjustment points for adjusting a length of the conductive member.

The housing may be cylindrical. The housing may be uniform in cross section along its length, or along least part least part of its length. The housing may be tube-shaped or at least partly tube-shaped. The housing may be elongate. The housing may be at least 5 times longer than it is wide.

Preferably, the housing is sealed from below by the conductive coupler.

The housing may be non-conductive. The housing may be plastic. The housing may be conductive.

The housing may engage with part of the conductive coupler by press fit arrangement. The conductive coupler may include a cylindrical portion which is received in an end of the housing.

The housing may include an aperture, through which an earth wire may be coupled to the conductive coupler. The aperture may be at least partially sealed using a grommet.

The conductive coupler may comprise a clamp member configured to clamp the conductive element that is to be cast into concrete, prior to casting into the concrete.

The conductive coupler may include a threaded member, wherein clamping is provided through relative rotation of the threaded member.

The clamp member may include a cut-out, configured to receive the conductive element.

The clamp member may comprise a threaded nut, wherein clamping is provided through rotation of the clamp member.

The clamp member may comprise an opening, configured to receive the conductive element, wherein the threaded nut closes the opening. The clamp member may comprise an opening, configured to receive the conductive element, wherein one or more screws clamps the conductive element in the opening.

The opening may have a curved edge, to at least partly conform to shape of the conductive element. The opening may have a profile including a first portion, curved at a first radius, and a second portion curved at a second radius. In such case, the clamp member may be configured to clamp conductive elements of different size, and therefor be multi-fit.

The conductive coupler may include an electrical earth coupling for coupling to an earth wire to earth the coupler and thus the conductive element. The electrical earth coupling may include a screw, for attaching an earth wire.

Multiple electrical safety systems may be coupled to each other by such earth wires.

The electrical safety system may be adapted to be used in a concrete floor or wall. The floor or wall may comprise a floor or wall of a wet area. The electrical safety system may be used in a pool. The electrical safety system may be used in a bathroom. The electrical safety system may be used in a public area. The electrical safety system may be used for earth grids in solar farms, power stations, generator pads and the like.

The conductive element may comprise metal reinforcing. The conductive element may comprise copper wire or copper netting configured to provide equipotential bonding of metal reinforcing.

The housing may be configured to be coupled to a like housing in an end-to-end arrangement. The housing may include a first end configured to be received in a second end of a like housing.

The housing may be sealed prior to adjusting the length thereof. This may prevent concrete from entering the housing.

In another form, the invention resides broadly in an electrical safety method comprising:

coupling a conductive coupler to a conductive element to be cast into concrete or similar material, the conductive coupler including a housing coupled thereto;

casting the conductive element, conductive coupler and at least part of the housing into concrete or similar material; and adjusting a length of the housing after being cast into the concrete or similar material to enable the housing to sit flush with a finished surface of or associated with the concrete or similar material.

The method may further include coupling the conductive coupler to an earth point.

The method may include adhering tiles or pavers to the concrete, wherein the tiles or pavers comprise the finished surface.

Any of the features described herein can be combined in any combination with any one or more of the other features described herein within the scope of the invention.

The reference to any prior art in this specification is not, and should not be taken as an acknowledgement or any form of suggestion that the prior art forms part of the common general knowledge.

### BRIEF DESCRIPTION OF DRAWINGS

Various embodiments of the invention will be described with reference to the following drawings, in which:

FIG. 1 illustrates a front view of an electrical safety system, in use, according to an embodiment of the present invention.

FIG. 2 illustrates a side view of a conductive coupler of the electrical safety system of FIG. 1.

FIG. 3 illustrates a top view of the conductive coupler of the electrical safety system of FIG. 1.

FIG. 4 illustrates a side view of a housing of the electrical safety system of FIG. 1.

FIG. 5 illustrates a top view of the housing of the electrical safety system of FIG. 1.

FIG. 6 illustrates a side view of a stainless-steel bolt of the electrical safety system of FIG. 1.

FIG. 7 illustrates a top view of the bolt of the electrical safety system of FIG. 1.

FIG. 8 illustrates a first partial installation of the electrical safety system of FIG. 1.

FIG. 9 illustrates a second partial installation of the electrical safety system of FIG. 1.

FIG. 10 illustrates a third partial installation of the electrical safety system of FIG. 1.

FIG. 11 illustrates a fourth partial installation of the electrical safety system of FIG. 1.

FIG. 12 illustrates a complete installation of the electrical safety system of FIG. 1.

FIG. 13 illustrates an electrical safety system, according to an alternative embodiment of the present invention.

FIG. 14 illustrates a side view of a coupling of the electrical safety system of FIG. 13.

FIG. 15 illustrates a front view of an electrical safety system, according to yet an alternative embodiment of the present invention.

FIG. 16 illustrates a top view of the electrical safety system of FIG. 15 with the bolt removed for clarity.

FIG. 17 illustrates a lower perspective view of the electrical safety system of FIG. 15 with the bolts and brass plate removed for clarity.

FIG. 18 illustrates a front view of the brass block of the system of FIG. 15.

FIG. 19 illustrates a top view of the brass block of the system of FIG. 15.

Preferred features, embodiments and variations of the invention may be discerned from the following Detailed Description which provides sufficient information for those skilled in the art to perform the invention. The Detailed Description is not to be regarded as limiting the scope of the preceding Summary of the Invention in any way.

### DESCRIPTION OF EMBODIMENTS

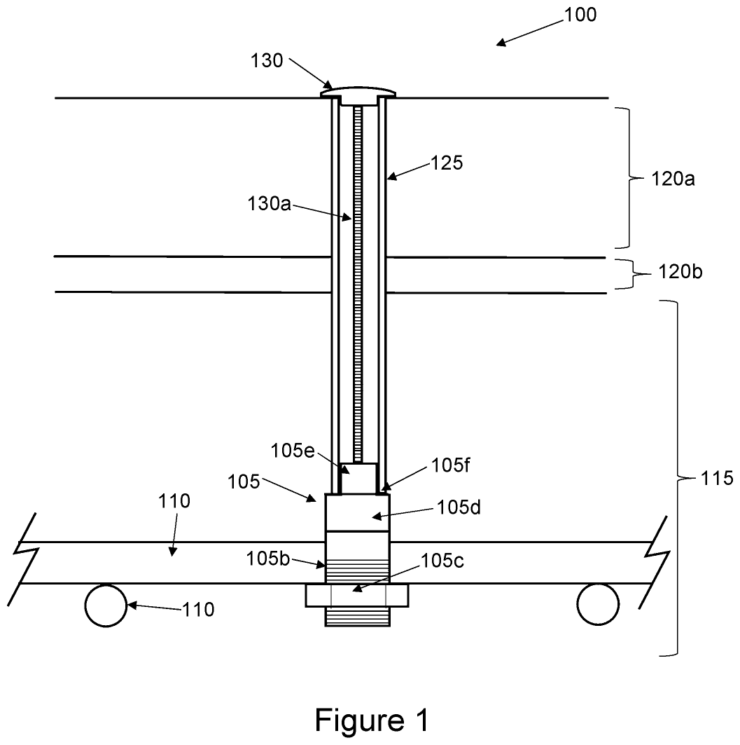

FIG. 1 illustrates a front view of an electrical safety system 100, in use, according to an embodiment of the present invention. The electrical safety system 100 enables easy testing of earthing associated with conductive elements, such as reinforcing bar, cast in concrete. As such, inspection costs are reduced, and faults in earthing are much more easily identifiable, which makes it quicker to identify and correct faults, which in turn increases safety.

The electrical safety system 100 includes a conductive coupler 105, for coupling the electrical safety system 100 to conductive elements in the form of metal reinforcing bars or mesh 110 (commonly known as rebar) that is cast into concrete 115 or similar material, such as cured or set material. The term ‘concrete’ used herein will be readily understood to cover variations of traditional concrete and similar material, including fibre reinforced concrete, lightweight concrete and concrete-like materials, and the like. Similarly, the methods and systems described herein may be adapted for use in relation to soil, roadbase and the like.

A tube-shaped housing 125 is coupled to the conductive coupler 105, and is partially cast into the concrete 115 and provides external access to the conductive coupler 105 and thereby the rebar for the purpose of earth testing.

The housing 125 extends up above the concrete 115, through an outer layer 120a and adhesive layer 120b. When connecting the coupler 105 (and housing 125) to the metal reinforcing bars or mesh 110, it is often unknown at what level (e.g. height above the reinforcing) the finished surface will be. In some cases, it may not even be finalised which surface materials will be used.

The housing 125, being tube-like and uniform in cross-section, is easily adjustable in length after being cast into the concrete, and after the pavers or tiles (or other finished surface) are laid, enabling the housing 125 to sit flush with the finished surface of or associated with the concrete. In particular, the housing 125 may simply be cut to length after being cast into the concrete 115.

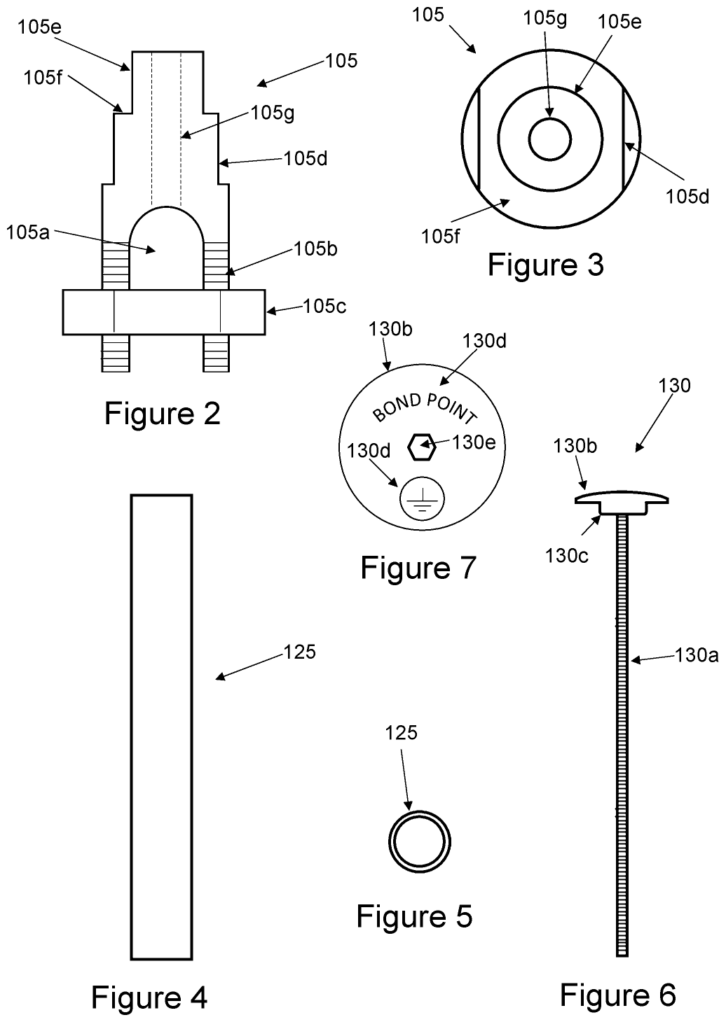

FIG. 2 illustrates a side view of the conductive coupler 105, and FIG. 3 illustrates a top view of the conductive coupler 105.

The conductive coupler 105 clamps the metal reinforcing 110. In particular, the coupler 105 includes an arch-shaped opening 105a, defined between threaded leg portions 105b. The threaded leg portions 105b comprise a threaded cylindrical body through which the opening 105a is defined. As such, a nut 105c is able to engage with the threaded leg portions 105b, to close the opening 105a from below, and wherein clamping of the metal reinforcing 110 (which is in the opening before the nut 105c is installed) is by rotation of the nut 105c.

As outlined above, the opening is arch-shaped and thus has a curved upper edge.

This shape of the upper edge is to at least partly conform to shape of the metal reinforcing 110, which is generally circular in cross-section. This ensures good electrical connection with the metal reinforcing 110, but also prevents twisting of the conductive coupler 105 relative to the metal reinforcing 110.

The generally cylindrical body of the conductive coupler 105 includes planar edges 105d defined on opposing sides of the conductive coupler 105 to provide surfaces on which a tool (e.g. wrench or spanner) may be used to prevent rotation of the conductive coupler 105. This is particularly useful as it enables the nut 105c is tightened without transferring any rotational force to the metal reinforcing 110.

A narrow cylindrical head 105e extends upwardly from the relatively larger cylindrical body, and is configured to engage with the housing in a press fit arrangement. In particular, the cylindrical head 105e is received in an end of the housing 125 to engage therewith in a press-fit arrangement and be supported against a shoulder 105f, defined at an upper edge of the cylindrical body. The head 104e also seals the housing from below, preventing concrete from entering the housing when poured.

FIG. 4 illustrates a side view of the housing 125, and FIG. 5 illustrates a top view of the housing 125. The housing 125 is tube shaped, and is substantially circular in cross section, and unfirm in cross section along its length. As such, the housing 125 may be cut along its length, while still having identical openings at its ends.

The housing 125 is elongate, and is at least about 5 times longer than it is wide. This provides a good balance between size and functionality. In particular, it enables a relatively small bolt head to cover an entire outer opening of the housing 125, as outlined below. The housing may be about 20mm in diameter or less.

Now turning back to FIG. 1, a stainless-steel bolt 130 extends from an outside of the housing 125, through the housing 125, and engages with the coupler 105 at an opposite end of the housing.

FIG. 6 illustrates a side view of the stainless-steel bolt 130, and FIG. 7 illustrates a top view of the bolt 130.

The bolt 130 includes a threaded shaft 130a extending downwardly from a head 130b of the bolt 130, which engages with a threaded aperture 105g of the conductive coupler 105. A lower portion of the head 130b comprises a plug-shaped member 130c which engages with an opening of the housing 125 in a press-fit arrangement. This essentially seals the housing 125 and ensures that dirt and debris does not fill the housing 125.

The stainless-steel bolt 130 is conductive, and being coupled to the conductive coupler 105, is conductively coupled to the coupler 105, and thereby to the metal reinforcing bars or mesh 110. As such, earthing of the metal reinforcing bars or mesh 110 may be tested using the head 130b of the bolt 130.

As best illustrated in FIG. 7, the head 130b includes 130d indicia thereon, which may include branding (trade marks), as well as information (e.g. an earth symbol), to enable a person to easily identify test points.

Finally, the head 130b comprises a dome-shaped cap, with a relatively small recessed hexagonal drive 130e. Such configuration enables the system 100 to be used on floors and similar surfaces without creating a trip hazard.

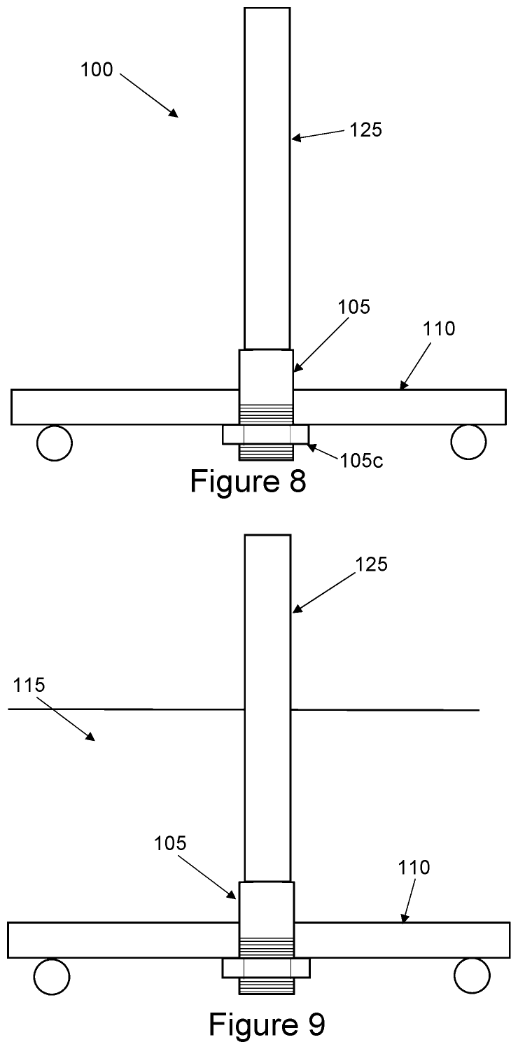

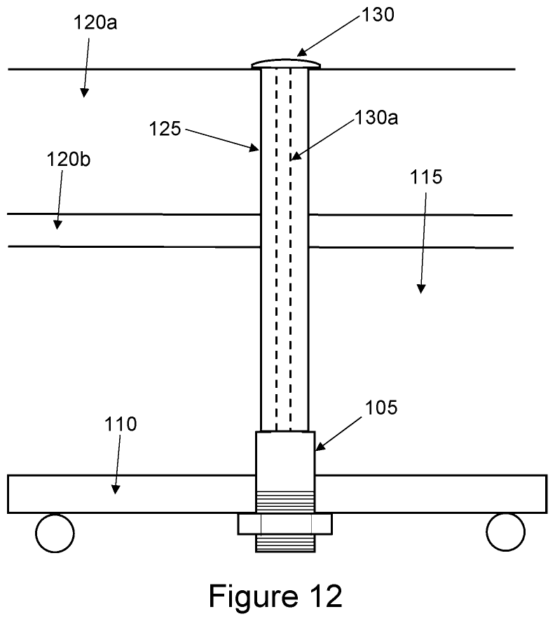

FIGS. 8 to 12 described below illustrate steps of an electrical safety method including installation of the electrical safety system 100, according to an embodiment of the present invention.

Initially, and as illustrated in FIG. 8, the coupler 105 is placed over reinforcing 110 that is to be cast into concrete such that the housing extends upwardly (or outwardly) towards what will ultimately become an outer surface of the concrete. The opening 105a of the coupler is placed over the reinforcing 110, and the nut 105c is tightened such that the coupler 105 is clamped to the reinforcing 110 and no longer needs to be held in place.

The housing 125 may be sealed off at a top thereof at this stage to prevent concrete 115 from entering the housing 125 during the pour. In alternative embodiments, the upper opening of the housing may be sealed, such that it is only opened when later cut.

Concrete 115 is then poured over the reinforcing 110, coupler 105, and part of the housing 125, such that the housing extends upwardly and out from the concrete 115, as illustrated in FIG. 9. The concrete 115 may then be left to cure, as is well known in the concreting industry.

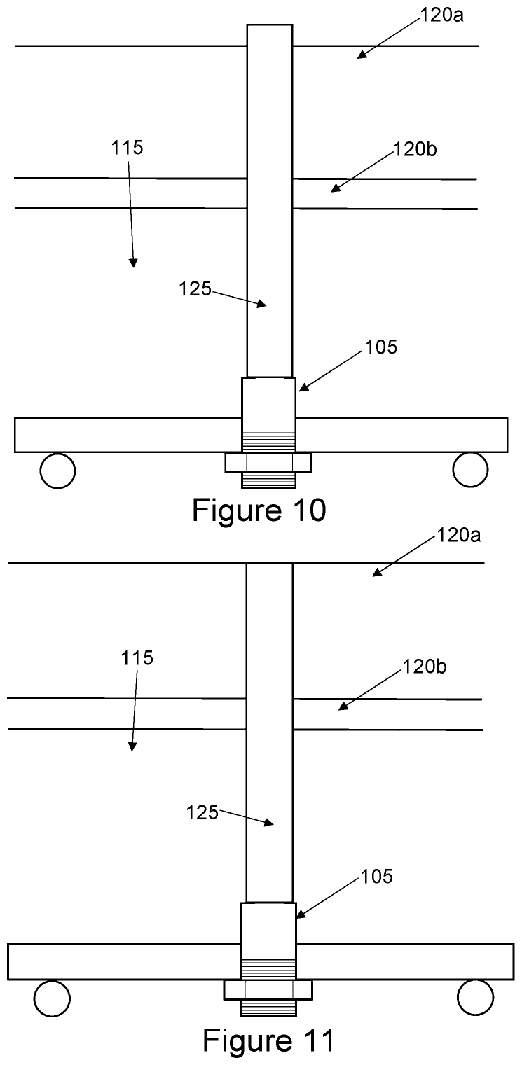

Pavers (or tiles) 120a are then adhered to the concrete 115 using adhesive 120b, and such that the housing extends outwardly beyond the finished surface thereof, as illustrated in FIG. 10. In alternative embodiments, other finishes may be applied at this stage instead of pavers (or tiles) including exposed aggregate surfaces, grey concrete or polished or honed concrete.

The exact thickness of the pavers 120a (or other surface) may not be known at this stage, and therefore the housing 125 may be chosen having a length that is sufficiently long to extend beyond a wide range of outer surface finishes.

Once the outer finish is complete, the housing 125 is then cut such that an outer opening thereof sits flush with the outer surface of the pavers 120a or other surface, as illustrated in FIG. 11. In case the housing 125 is sealed from above, cutting the housing 125 will create an opening in an end thereof.

The bolt 130 is then installed and tightened, such that it engages with the coupler 105, and clamps down on the opening of the housing 125, thereby sealing the housing.

When earth testing the reinforcing, a test instrument may be placed against the head of the bolt and continuity with earth, or any other suitable earth testing may be performed.

In some embodiments, multiple like electrical safety systems 100 may be placed in a structure, enabling the reinforcing to be tested at multiple points. As an illustrative example, test points may be placed periodically in a structure and tested against each other, and against a common earth.

While the above example illustrates metal reinforcing, in some areas copper wire or net (mats) may be placed on and coupled to the metal reinforcing to ensure equipotential bonding between pieces of reinforcing. In such case the copper wire (or net, mat) will generally have a much smaller diameter than the reinforcing. In such case the coupler 105 may be adjusted in size to suit the smaller copper wire.

In some embodiments, in addition to providing a test point, electrical safety systems may also provide earth points to the conductive reinforcing or other material.

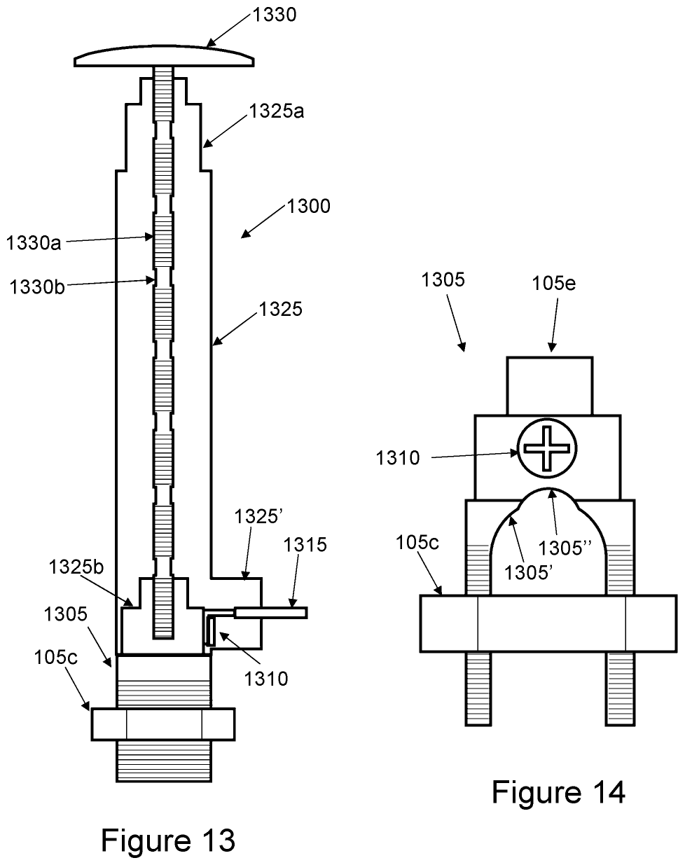

FIG. 13 illustrates an electrical safety system 1300, according to an alternative embodiment of the present invention. The electrical safety system 1300 is installed and used in a similar manner to the system 100, described above.

The electrical safety system 1300 includes a coupler 1305, a housing 1325 and a bolt 1330, similar to the coupler 105, housing 125 and bolt 130 of the system 100. The coupling 1305 includes an electrical earth coupling 1310 in the form of a screw, which is configured to electrically couple an earth wire 1315 to the conductive coupling 1305. FIG. 14 illustrates a side view of the coupling 1305.

The earth wire 1315 exits through an opening 1325′ in a lower end of the housing 1325 and may be coupled directly to a switch box, junction box, or an earth point, for example, either directly or indirectly. As an illustrative example, multiple electrical safety systems 1300 may be coupled to each other by such earth wires, and to a switch box, junction box, or an earth point, for example.

The opening 1325′ may be configured to be coupled to electrical conduit, which thereby provides shielding to the earth wire 1315 under the concrete. Alternatively, the opening 1325′ may include a grommet (not illustrated) enabling the wire 1315 to exit the housing 1325, but preventing concrete from entering the housing 1325, effectively sealing the housing 1325 from below.

The earth wire 1315 is illustrated as a short wire for clarity, but the skilled addressee will readily appreciate that the earth wire 1315 is typically several meters long, and may be of any suitable length to be coupled to the earth point.

The coupler 1305 includes an opening 1305a, similar to the opening 105a, but having a profile including a first portion 1305′, curved at a first radius, and a second portion 1305″ curved at a second radius. This enables the coupler 1305 to clamp conductive elements (e.g. reinforcing) of different sizes, and therefore be multi-fit.

The housing 1325 includes an upper stepped end 1325a and a lower corresponding stepped end 1325b, which enables like housings 1325 to be coupled to each other and extended in a lengthwise direction. In particular, the upper end 1325a is configured to be received in a lower end 1325b of a like housing 1325.

Finally, the bolt 1330 includes a plurality of threaded portions 1330a, separated by narrow portions 1330b, thereby defining adjustment points for adjusting a length of the bold 1330. In particular, the bolt 1330 may be cut at any of the narrow portions 1330b without damaging the threads of the threaded portions 1330a. This is useful given that the bolt 1330 may be too long, depending on where the housing is cut.

In other embodiments, the coupler may comprise any suitable clamp member. In one embodiment, the clamp member may comprise an opening, configured to receive the metal reinforcing bars or mesh 110 (or other conductive element), wherein one or more screws clamps the conductive element in the opening.

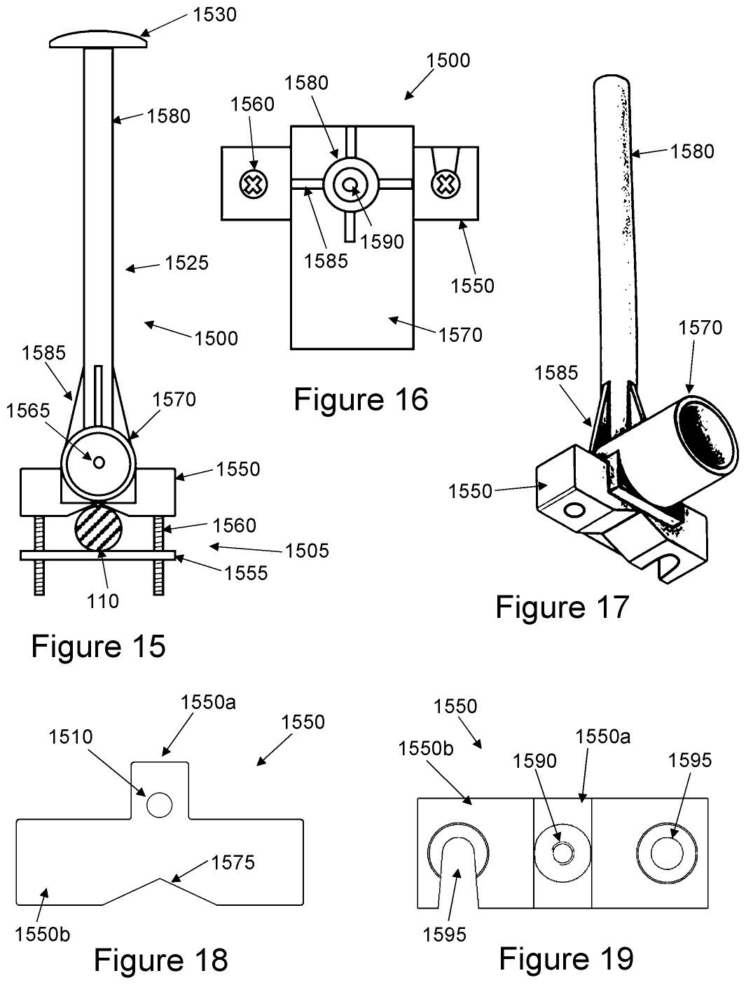

FIG. 15 illustrates a front view of an electrical safety system 1500, according to yet an alternative embodiment of the present invention. The electrical safety system 1500 is installed and used in a similar manner to the system 1300, described above.

The electrical safety system 1500 includes a coupler 1505, a housing 1525 and a bolt 1530, similar to the coupler 1305, housing 1325 and bolt 1330 of the system 1300.

FIG. 16 illustrates a top view of the electrical safety system 1500 with the bolt 1530 removed for clarity.

The coupling 1505 comprises a brass block 1550, a brass plate 1555 and first and second bolts 1560, configured to couple the brass block 1550 and the brass plate 1555 in a clamping arrangement, such that the bolts 1560 may be tightened to clamp the coupling around a piece of metal reinforcing bars or mesh 110. In this regard the bolts extend through the block 1550, and engage with threaded apertures of the plate 1555.

FIG. 17 illustrates a lower perspective view of the electrical safety system 1500 with the bolt 1530, first and second bolts 1560, and brass plate 1555 removed for clarity. FIG. 18 illustrates a front view of the brass block 1550, and FIG. 19 illustrates a top view of the brass block 1550.

As best illustrated in FIG. 18, the brass block 1550 includes upper and lower members 1550a, 1550b. The upper lower member 1550b is configured to engage with the rebar, and the upper member 1550a is configured to be received in and engage with the housing 1525. The upper member 1550a includes an electrical earth coupling 1510 in the form of a threaded aperture, which is configured to receive a screw (not illustrated) to retain an earth wire (not illustrated) to the brass block 1550, in a similar manner to that outline above. The housing 1525 includes an aperture 1565 aligning with the coupling 1510, enabling attachment of the earth wire and screw or bolt through a conduit coupling 1570 thereof. The conduit coupling 1570 comprises a tube-shaped member which is configured to engage with conduit in a press-fit arrangement.

The screw or bolt not only couples the earth wire to the brass block 1550, but also couples the housing 1525 and brass block 1550, and seals the aperture 1565. As such, the screw or bolt will generally be used to couple the housing 1525 and brass block 1550, regardless of whether an earth wire is coupled to the brass block or not (noting that the rebar may be earthed elsewhere).

As best illustrated in FIG. 18, the brass block 1550 includes a v-shaped cut-out 1575, configured to engage with the rebar (to prevent the block 1550 from sliding laterally with reference to the rebar. Being a v-shaped, the cut-out 1575 can be used with rebar of different sizes, and therefore be multi-fit.

Now turning back to FIGS. 15 and 17, the housing 1525 comprises a vertical tube 1580 extending upwardly from the conduit coupling 1570, and directly above the brass block 1550. The tube 1580 provides direct access to the brass block 1550 from above.

As best illustrated in FIG. 19, the block 1550 includes a threaded bolt aperture 1590 in its upper portion 1550a, which in use is located directly below the tube 1580, to enable the bolt 1530 to engage therewith from above.

The block 1550 further includes openings 1595 for bolts, which extend through the lower portion 1550a of the block 1550 from top to bottom, and one of which is open from the side. This simplifies the installation procedure, as the bolt 1560 need not be completely removed from the plate 1555.

The openings 1595 are countersunk, and the bolt aperture 1590 also has a countersunk tapered opening, which helps guide the bolt 1530 into the aperture 1590. This is particularly relevant when the bolt is installed at a later time from above.

The bolt 1530 may be sized to fit with the housing 1525 in uncut form. The housing 1525, and in particular the tube 1580, will however be cut to the level of the finished surface (e.g. concrete or similar surface). As such, the bolt 1530 may be shortened by the amount corresponding to that removed from the top of the tube 1580. As a result, the removed top of the tube 1580 may function as a guide to assist a worker when shortening the bolt 1530.

The electrical safety systems described above may be adapted to be used in a concrete floor or wall, including a floor or wall of a wet area or partially wet area.

As an illustrative example, the electrical safety systems and methods may be used in domestic or commercial wet area construction and may enable testing for compliance as per ASNZS 3000,2018 (or other similar standards or guidelines). In such case, connections can be made anywhere to the reinforcing steel attached to the slab/walls of the area and may be in multiple different points.

In multi-level construction, at least one system per floor may be required or used. Each system may be placed in a riser cupboard/void, in the floor of a switchboard cupboard or anywhere adjacent to the metal reinforcing (or other conductive element) of each floor.

The electrical safety systems and methods may be used in a pool, spa, splash area or environment associated therewith. In the case of a domestic pool, the system may be installed in a coping or bond beam, and be coupled to any surrounding metal. In commercial pools, the systems can be installed as test points coupled to reinforcing only, or as interconnected test points coupled to a common earth. Furthermore, in commercial/public pools, test points may be provided every 3-6meters, and test points may be provided in the floor of the pool, and thus submerged when the pool is in use.

Similarly, the systems and methods may be used in public spaces or structures, such as in BBQ pavilions, or any areas with power associated with reinforced concrete slabs. Furthermore, the systems and methods may be used in relation to power stations, solar farms, large earthgrids and/or in lightning protection grids.

As outlined above, the couplings are conductive, and may be formed of brass or other similar or suitable material. Preferably, the couplings are cast of a single piece with a nut. The housing may be non-conductive and may be formed of plastic. Alternatively, the housing may be formed of a metal tube and may be conductive.

While the above examples illustrate and describe metal reinforcing and copper wire cast into concrete, the skilled addressee will readily appreciate that the teachings may be applied to a wide variety of conductive elements, and may be used together with conductive elements that are not cast into concrete. As an illustrative example, the metal fencing may be coupled to the earth wire, and equipotential testing may be performed between metal fencing and the bolt.

By coupling many conductive elements together to a common earth, the conductive elements have substantially the same electrical potential, and as such, electric current is unlikely to flow between objects (e.g. by a person), even in case of a fault. Furthermore, in case of an electrical fault, where one of the conductive objects becomes “live”, it is immediately directed to the earth, upon which a circuit breaker may detect the fault and interrupt the circuit.

While the systems include a bolt, which may be used for testing, in case a fault is identified, the bolt may be removed, providing a window into the concrete through the housing, potentially enabling a source of the fault to be identified (e.g. in the case of physical damage). As a result, faults may be more easily localised, potentially reducing the cost associated with fault identification.

After the systems described above are installed, testing of the earthing may be greatly simplified. In particular, the user may measure a resistance between the bolts and the earth, which may be at the main switchboard associated with the building. In normal circumstances, the resistance should be low, e.g. below 0.5 Ω. Resistance is then measured between each additional bolt (in case multiple systems are used together) and the earth.

The resistance being low ensures that there is no (or minimal) voltage differential between conductive elements, should a fault occur. If, on the other hand, the earth is damaged, the resistance is high (or infinite), a substantial voltage drop may occur between conductive element, which can be dangerous in case of electrical fault, and must be further investigated.

Advantageously, the methods and systems described above provide a simple, cost effective and aesthetically pleasing test points for earth testing. This may in turn simplify testing, which may in turn increase safety. The methods and systems are particularly useful in scenarios where the final outer surface of concrete is not known or may change, e.g. through installation of tiles, pavers or the like.

In the present specification and claims (if any), the word ‘comprising’ and its derivatives including ‘comprises’ and ‘comprise’ include each of the stated integers but does not exclude the inclusion of one or more further integers.

Reference throughout this specification to ‘one embodiment’ or ‘an embodiment’ means that a particular feature, structure, or characteristic described in connection with the embodiment is included in at least one embodiment of the present invention. Thus, the appearance of the phrases ‘in one embodiment’ or ‘in an embodiment’ in various places throughout this specification are not necessarily all referring to the same embodiment. Furthermore, the particular features, structures, or characteristics may be combined in any suitable manner in one or more combinations.

In compliance with the statute, the invention has been described in language more or less specific to structural or methodical features. It is to be understood that the invention is not limited to specific features shown or described since the means herein described comprises preferred forms of putting the invention into effect. The invention is, therefore, claimed in any of its forms or modifications within the proper scope of the appended claims (if any) appropriately interpreted by those skilled in the art.

1. An electrical safety system comprising:
a conductive coupler, for coupling the electrical safety system to a conductive element and be cast into concrete or similar material with the conductive element; and
a housing, coupled to the conductive coupler, configured to be at least partially cast into the concrete or similar material to provide external access to the conductive coupler and thereby the conductive element,
wherein a length of the housing is adjustable after being cast into the concrete or similar material to enable the housing to sit flush with a finished surface of or associated with the concrete.

2. The electrical safety system of claim 1, wherein the housing is configured to be cut to length after being cast into the concrete.

3. The electrical safety system of claim 1, wherein the housing is sealable.

4. The electrical safety system of claim 1, wherein the housing is adapted to be sealed by a conductive member that extends from an outside of the housing, through the housing, to the conductive coupler.

5. The electrical safety system of claim 4, wherein the conductive member includes a threaded portion, configured to engage with a corresponding threaded portion of the conductive coupler.

6. The electrical safety system of claim 4, wherein the conductive member is adjustable in length.

7. The electrical safety system of claim 4, wherein the conductive member includes a plurality of threaded portions, separated by narrow portions, thereby defining adjustment points for adjusting a length of the conductive member.

8. The electrical safety system of claim 1, wherein the housing is uniform in cross section along at least part of its length.

9. The electrical safety system of claim 1, wherein the housing is at least partly tube-shaped.

10. The electrical safety system of claim 1, wherein the housing is sealed from below by the conductive coupler.

11. The electrical safety system of claim 1, wherein the housing is non-conductive.

12. The electrical safety system of claim 1, wherein the housing includes an aperture, through which an earth wire may be coupled to the conductive coupler.

13. The electrical safety system of claim 1, wherein the conductive coupler comprises a clamp member configured to clamp the conductive element that is to be cast into concrete, prior to casting into the concrete.

14. The electrical safety system of claim 13, wherein the conductive coupler includes a threaded member, wherein clamping is provided through relative rotation of the threaded member.

15. The electrical safety system of claim 13, wherein the clamp member includes a cut-out, configured to receive the conductive element.

16. The electrical safety system of claim 1, wherein the conductive coupler includes an electrical earth coupling for coupling to an earth wire to earth the coupler and thus the conductive element, the electrical earth coupling including a screw, for attaching an earth wire.

17. The electrical safety system of claim 1, adapted to be used in a concrete floor or wall.

18. The electrical safety system of claim 17, wherein the floor or wall comprises a floor or wall of a wet area or pool.

19. The electrical safety system of claim 1, wherein the conductive element comprises metal reinforcing.

20. An electrical safety method comprising:
coupling a conductive coupler to a conductive element to be cast into concrete or similar material, the conductive coupler including a housing coupled thereto;
casting the conductive element, conductive coupler and at least part of the housing into concrete or similar material; and
adjusting a length of the housing after being cast into the concrete or similar material to enable the housing to sit flush with a finished surface of or associated with the concrete or similar material.
